(19) United States
(12) Patent Application Publication
(10) Pub. No.: US 2008/0124453 A1
(43) Pub. Date: May 29, 2008

(54) IN-SITU DETECTION OF GAS-PHASE PARTICLE FORMATION IN NITRIDE FILM DEPOSITION

(75) Inventors: DAVID BOUR, Cupertino, CA (US); Ronald P. Stevens, San Ramon, CA (US); Jacob W. Smith, Santa Clara, CA (US); Sandeep Nijhawan, Los Altos, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Matrials, Inc., Santa Clara, CA (US)

(21) Appl. No.: 11/564,187

(22) Filed: Nov. 28, 2006

(51) Int. Cl. C23C 16/00; C23C 14/54

(52) U.S. Cl. 427/10; 118/712

(57) ABSTRACT

Systems and methods for in-situ monitoring of the formation of parasitic particles during the deposition of a III-V nitride film with, e.g., metal-organic chemical vapor deposition (MOCVD) are described. In accordance with certain embodiments, at least one light source capable of generating a light beam at a desired wavelength is positioned relative to a reaction chamber so as to pass a light beam into the reaction chamber. Multiple optical detectors capable of detecting light from the beam are positioned relative to the reaction chamber to monitor desired reaction and growth conditions. More particularly, a first optical detector is positioned so as to detect light reflected from a deposition surface within the reaction chamber so as to monitor growth rate and/or composition of a film during deposition. At least a second optical detector is positioned off-axis relative to the deposition surface so as to detect light scattered by gas-phase particle formed above the deposition surface so as to monitor gas-phase particle formation during film deposition.

### BACKGROUND OF THE INVENTION

Group III-V semiconductors are increasingly being used in light-emitting diodes (LEDs) and laser diodes (LDs). Specific III-V semiconductors, such as gallium nitride (GaN), are emerging as important materials for the production of shorter wavelength LEDs and LDs, including blue and ultra-violet emitting optical and optoelectronic devices. Thus, there is increasing interest in the development of fabrication processes to make low-cost, high-quality III-V semiconductor films.

One widely used process for making III-V nitride films like GaN is hydride vapor-phase epitaxy (HVPE). This process includes a high-temperature, vapor-phase reaction between gallium chloride (GaCl) and ammonia (NH₃) at a substrate deposition surface. The GaCl precursor is produced by passing hydrogen chloride (HCl) gas over a heated, liquid gallium supply (melting point 29.8° C.). The ammonia may be supplied from a standard gas source. The precursors are brought together at the heated substrate, where they react and deposit a layer of GaN. The HVPE deposition rate is high (e.g., up to 100 μm/hr) and provides a relatively fast and cost effective method of making GaN films.

Another process called metal-organic chemical vapor deposition (MOCVD) is used to form III-V nitride films. MOCVD uses a reasonably volatile metallorganic Group III precursor such as trimethylgallium (TMGa) or trimethylaluminum (TMAl) to deliver the Group III metal to the substrate where it reacts with the nitrogen precursor (e.g., ammonia) to form the III-V nitride film,

MOCVD nitride films are typically deposited at lower temperature than HVPE films, allowing the fabrication process to have a lower thermal budget. It is also easier to combine two or more different Group III metallorganic precursors (e.g., Ga, Al, In, etc.) and make alloy films of GaN (e.g., AlGaN, InGaN, etc.). Dopants may also be more easily combined with the precursors to deposit an in-situ doped film layer.

MOCVD film depositions, however, generally has slower deposition rates than HVPE. MOCVD typically deposits a film at about 5 μm/hr or less compared with 50 μm/hr for HVPE. The slower deposition times make MOCVD a lower throughput and more expensive deposition process than HVPE.

Several approaches have been tried to increase the throughput of GaN depositions with MOCVD: In one approach, batch reactors have been tried that are capable of simultaneously growing films on many wafers or over large areas. In a second approach, attempts were made to increase the rate of GaN film growth and heterostructures. Both approaches have had difficulties.

Scale up to large areas has proved difficult because the GaN must be grown at relatively high pressures (e.g., several hundred Torr), and at these pressures the flow velocity in a large reactor is low, unless the total flow through the reaction is made extraordinarily high. Consequently, the precursor stream becomes depleted of reactants over a short distance, making it difficult to grow a uniform film over a large area.

Attempts to increase the deposition rates of a GaN film by increasing the concentration (i.e., partial pressures) of the organo-gallium and ammonia precursors have also proved difficult. FIG. 1A shows a graph of a growth rate for a GaN film as a function of the total pressure in the MOCVD reactor. These graphs are based on simulations by STR of GaN film growth in a Thomas Swan reactor with a close-coupled showerhead injector. The graph shows a steep drop in the rate as the pressure in the reactor increases above about 300 torr.

The decrease in GaN film growth rate with increasing MOCVD reactor pressure is attributed to the formation of gas-phase parasitic particles that consume the Ga and N precursors that would otherwise be used to grow the film. These parasitic particles form in a thin thermal boundary layer over the wafer substrate, where local gas temperatures become sufficiently high to promote a pyrolytic reaction between the Group III precursors and ammonia (the nitrogen precursor). Once formed, the hot, suspended (by thermophoresis) particles become nuclei for additional deposition, thereby growing and further depleting reactants from the gas stream, until they are flushed out of the chamber. Thus, there is competition between the desired film growth and the parasitic particle growth. Parasitic particle formation increases when the partial pressures of the Group III and/or Group V precursors increase, or when the thermal boundary layer around the wafer substrate is expanded.

In the case of GaN films grown with a trimethylgallium precursor, the film growth rate eventually saturates with respect to the trimethylgallium flow, making it difficult to realize growth rates greater than about 5 μm/hr. The formation of the parasitic particles can also degrade the optoelectronic qualities of the deposited GaN film.

Because the parasitic particle formation depends on the partial pressures of the Group III and V precursors, it may be possible to increase the growth rate of the MOCVD deposited film by diluting the precursor gas stream with more carrier gas (e.g., hydrogen (H₂), helium, etc.). However, attempts to dilute the precursor gas stream hurt the quality of the III-V film that was deposited. Maintaining high partial pressures of the precursors, especially a high ammonia partial pressure in the case of nitride film depositions, appears to be beneficial in the growth of high quality films.

Parasitic particle formation in MOCVD film depositions can be even more severe for alloys of gallium nitride. FIG. 1B, for example, shows a graph of a STR simulation of the deposition rate of AlGaN as a function of the pressure in an Aixtron planetary reactor. The graph shows an even steeper drop off in the film formation rate versus reactor pressure during the formation of a AlGaN film than for an unalloyed GaN film. Similar decreases in film growth rates were shown in simulations for Thomas Swan and Veeco reactor geometries.

AlGaN films are used in LED heterostructures where a p-type layer is grown over a InGaN well active region. It is therefore beneficial to grow the AlGaN film with a reasonably high hole concentration, and free of nonradiative or compensating defects. Unfortunately, high total pressures and high ammonia flows are best for growing AlGaN films with these qualities, but growing these films with the requisite Al content by MOCVD is extremely challenging due to the formation of the parasitic particles.

In another example, InGaN film growth is also limited by parasitic particle formation. FIG. 1C shows a graph of an InGaN film growth rate as a function of reaction pressure. The graph was derived from growth simulation done with a Thomas Swan showerhead reactor geometry at various pressures. While the formation of parasitic particles in MOCVD depositions of InGaN is not as pronounced as for AlGaN, it is still significant enough to limit the growth rate of the films. InGaN films have applications in the quantum well active regions of laser diodes and LEDs. Without the formation of the parasitic particles, growth of InGaN films could be performed at higher pressures and higher ammonia flow, both of which would be beneficial for the optoelectronic quality (e.g., high internal efficiency) and p-type doping in LDs and LEDs. Thus, there is a need for systems and methods that control and/or monitor parasitic particle formation while increasing the throughput of MOCVD formed III-V nitride films.

### BRIEF SUMMARY OF THE INVENTION

To address such needs and others, in certain aspects of the invention, a method for in-situ monitoring of gas-phase particle formation during metal organic chemical vapor deposition (MOCVD) of Group III-V nitride films is provided. The method generally comprises initiating deposition of a Group III-V nitride film on a substrate in a MOCVD reaction chamber; generating a light beam at a desired wavelength and directing the light beam within the MOCVD reaction chamber so as to pass the light beam through the MOCVD reaction chamber to the surface of the substrate disposed within the MOCVD reaction chamber during deposition of the Group III-V nitride film. Light reflected from the surface of the substrate disposed within the MOCVD reaction chamber during deposition of the Group III-V nitride film is then detected at a first optical detector positioned at a predetermined angle relative to at least one light source so as to receive reflected light from the substrate and exclude incident light. The first optical detector is generally configured to monitor growth rate and/or composition of the Group III-V nitride film during deposition. Light scattered by gas-phase particles formed above the surface of the substrate disposed within the MOCVD reaction chamber is also detected at a second optical detector positioned off-axis relative to the sample so as to receive scattered light from gas-phase particles. In accordance with the invention, the second optical detector is configured to monitor gas-phase particle formation during deposition of the Group III-V nitride film.

In certain embodiments, the methods further include controlling operating parameters of the MOCVD reaction chamber to minimize gas-phase particle formation based, in part, on readings from the second optical detector.

In another aspect, an apparatus for in-situ monitoring of gas-phase particle formation during metal organic chemical vapor deposition (MOCVD) of Group III-V nitride films is provided. The apparatus generally comprises: an MOCVD reaction chamber configured for deposition of a Group III-V nitride film; at least one light source capable of generating a light beam at a desired wavelength and positioned relative to the MOCVD reaction chamber so as to pass the light beam into the MOCVD reaction chamber to the surface of a sample disposed within the MOCVD reaction chamber during deposition of a Group III-V nitride film; a first optical detector capable of detecting light reflected from the surface of the sample disposed within the MOCVD reaction chamber and positioned at a predetermined angle relative to at least one light source so as to receive reflected light from the sample and exclude incident light; and a second optical detector capable of detecting light scattered by gas-phase particles formed above the surface of the sample disposed within the MOCVD reaction chamber and positioned off-axis relative to the sample so as to receive scattered light from gas-phase particles. Again, the first optical detector is configured to monitor growth rate and/or composition of the Group III-V nitride film during deposition, and the second optical detector is configured to monitor gas-phase particle formation during deposition of the Group III-V nitride film.

These and other aspects of the invention will be described in more detail throughout the present specification and more particularly below in conjunction with the following drawings.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIGS. 1A-C are graphs plotting the deposition rates of III-V nitride films as a function of pressure in a reaction chamber;

FIG. 2 provides a schematic illustration of a structure of a GaN-based LED;

FIG. 3 is a flowchart illustrating a deposition process including in-situ monitoring according to embodiments of the invention;

FIG. 4 is a simplified representation of an exemplary CVD apparatus that may be used in implementing certain embodiments of the invention;

FIG. 5 provides a schematic illustration of a multichamber cluster tool used in embodiments of the invention;

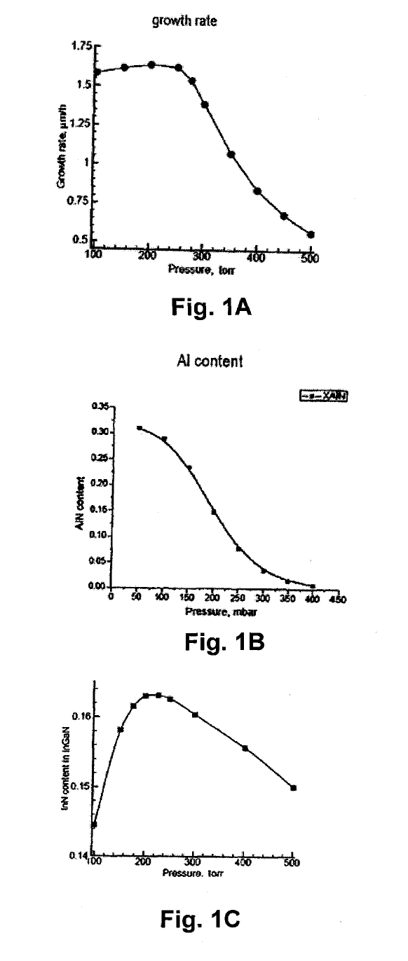

### DETAILED DESCRIPTION OF THE INVENTION

In certain aspects of the invention, systems and methods for the in-situ monitoring of gas-phase formation of parasitic particles during the deposition of a III-V nitride film with, e.g., metal-organic chemical vapor deposition (MOCVD) are described. In accordance with certain embodiments, at least one light source capable of generating a light beam at a desired wavelength is positioned relative to a reaction chamber so as to pass a light beam into the reaction chamber. Multiple optical detectors capable of detecting light from the beam are positioned relative to the reaction chamber to monitor desired reaction and growth conditions. More particularly, a first optical detector is positioned so as to detect light reflected from a deposition surface within the reaction chamber so as to monitor growth rate and/or composition of a film during deposition. At least a second optical detector is positioned off-axis relative to the deposition surface so as to detect light scattered by gas-phase particle formed above the deposition surface so as to monitor gas-phase particle formation during film deposition.

Without intending to be limited by theory, as process gases are introduced to a reaction chamber and heat up, GaN is formed in the gas phase and GaN particles nucleate (J. Phys. Chem. A 2005, 109, 133-137). Thermophoresis will cause heated gases to convect away from the substrate surface and into the bulk gas flow, allowing for particle nucleation and growth. In accordance with the systems and methods of the invention, in-situ gas-phase particle formation may be monitored, and process conditions adjusted so as to minimize particle formation. In this way, the reaction environment may be maintained under optimal conditions to provide for stable film growth while minimizing parasitic particle formation. For instance, partial pressures of reactants may be adjusted to their maximum values just below the threshold for parasitic particle formation.

By way of example, the particle suppression methods and systems of the invention, e.g., allow the Group III and Group V precursors to be supplied to the reaction chamber at optimized partial pressures for growing high quality III-V films with MOCVD. The ability to optimize the partial pressures of the film forming precursors without also forming more parasitic particles allows the III-V films to be grown at faster deposition rates (e.g., rates of about 5 μm/hr or more), and with higher optoelectronic quality (e.g., higher internal efficiency, superior p-type doping, etc.) as compared to films grown at lower, non-optimized reactor pressures.

In another aspect, the multiple detector configurations of the present invention may be used to monitor reactor chamber cleaning operations. More particularly, in certain embodiments, the second optical detector may be used to detect light scattered by gas-phase particles during reaction chamber cleaning, such that an absence, or substantial absence, of gas-phase particles indicates a chamber clean end point.

### I. Exemplary III-V Film Structures

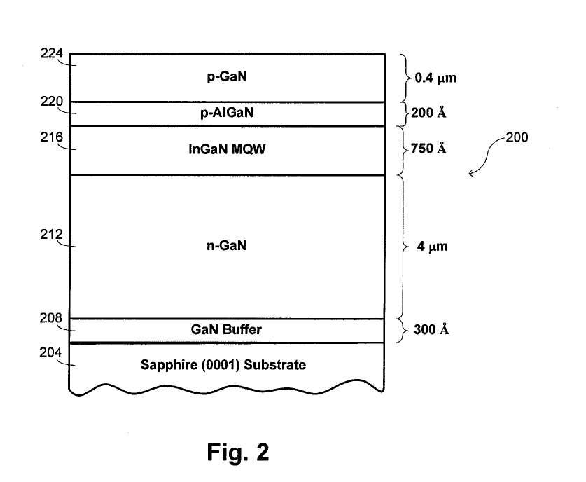

Embodiments of the systems and methods described may be used to form III-V devices that act as light emitting diodes and/or laser diodes, among other devices. FIG. 2 shows an example of a III-V device that may be made using the present systems and methods. A GaN-based LED structure 200 is shown formed over a sapphire (0001) substrate 204. An n-type GaN layer 212 is deposited over a GaN buffer layer 208 formed over the substrate. An active region of the device is embodied in a multi-quantum-well layer 216, shown in the drawing to comprise an InGaN layer. A pn junction is formed with an overlying p-type AlGaN layer 220, with a p-type GaN layer 224 acting as a contact layer.

Other III-V devices may also be made by the present invention, including laser diodes (LDs), high-electron mobility transistors, and other opto-electronic devices.

### II. Exemplary In-Situ Methods

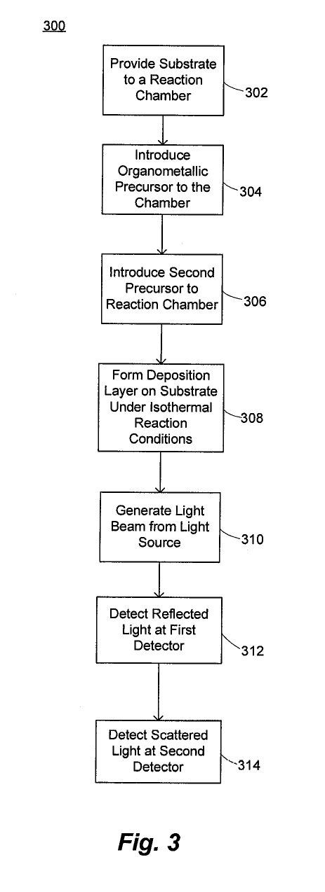

FIG. 3 shows a flowchart illustrating steps in processes 300 of in-situ monitoring of gas-phase particle formation during deposition according to embodiments of the invention. The process 300 includes providing a substrate upon which the deposition layer will be formed to a reaction chamber 302. The reaction chamber may generally include a susceptor which supports the substrate and a top-plate disposed above the susceptor and substrate to define, at least in part, a reaction chamber.

The deposition layer may be, e.g., a nucleation layer, a epitaxial layer, etc., and may include a single Group III metal or an alloy, depending on the end use of the device being constructed, and the specific step of the deposition process. Deposition temperatures and pressures may vary, depending on the specific layer and starting materials of interest, as recognized by those skilled in the art. In certain embodiments, the substrate may be any substrate that a group III-V nucleation layer can be formed by, e.g., MOCVD. However, the invention is not so limited, e.g., hydride vapor phase epitaxy (HVPE) may alternatively be used in other embodiments. These may include, for example, substrate wafers made from sapphire (Al₂O₃), substantially pure silicon (Si), silicon carbide (SiC), spinel, zirconium oxide, as well as compound semiconductor substrates such as gallium-arsenide (GaAs), lithium gallate, indium phosphide (InP), and single-crystal GaN among other substrates.

With the substrate in the reaction chamber, the film forming precursors may be introduced to start the deposition of the deposition layer. In the flowchart shown in FIG. 3, embodiments of the process may include introducing an organometallic precursor to the reaction chamber 304. The organometallic precursor may include a Group III metal and a carbon group, among other constituents. For example, the precursor may include an alkyl Group III metal compound such as an alkyl aluminum compound, an alkyl gallium compound, and/or an alkyl indium compound, among others. Specific precursor examples may include trimethylaluminum (TMA), triethyl-aluminum (TEA), trimethylindium (TMI), triethylindium (TEI), trimethylgallium (TMG), and triethylgallium (TEG). Larger sized alkyl groups, such as propyl, pentyl, hexal, etc., may also be combined with the Group III metal. Different sized alkyl groups may also be combined in the same precursor, such as ethyldimethylgallium, methyldiethyl-aluminum, etc. Other organic moieties such as aromatic groups, alkene groups, alkyne groups, etc. may also be part of the organometallic precursor.

Two or more organometallic precursors may be introduced to the reaction chamber to react and form a layer that includes a metallic alloy. For example, the organometallic precursors may include two or more Group III metals (e.g., Al, Ga, In) that form a nitride of a Group III alloy on the substrate, such as AlGaN, InGaN, InAlN, InAlGaN, etc. In AlGaN, for example, TMG and TMA may be introduced together into the reaction chamber with a nitrogen precursor (e.g., ammonia) to form the alloyed III-V layer.

The organometallic precursor may also bc a halogenated precursor, with the halogen group attached to either the metal atom, the organic moiety, or both. Examples include diethylgallium chloride, chloromethlydiethylgallium, chlorodiethylgallium chloride, etc.

A second precursor may be introduced to the reaction chamber 306 that reacts with the organometallic precursor in a reaction zone around the deposition surface of the substrate. When the deposition layer is a metal-nitride layer, the second precursor may be a nitrogen containing precursor, such as ammonia (NH₃). The second precursor may flow in a separate gas stream into the reaction chamber that intersects with the organometallic precursor gas stream in a space in the heated reaction zone above the substrate.

Carrier gases such as helium, hydrogen, argon, or nitrogen may be used to facilitate the flow of the precursors and particle suppression compounds in the reaction chamber, as well as adjust the total pressure in the chamber. The carrier gas may be premixed with the precursor gas before entering the chamber, and/or may enter the chamber in an unmixed state through a separate flow line.

When the precursors react in the reaction zone, least a portion of the reaction products forms a deposition layer on the substrate 308. A light from a light source is generated and directed into the reaction chamber at a desired wavelength 310 and a desired position relative to the reaction chamber so as to pass light onto the deposition surface. In certain embodiments, a red or green laser, a He—Ne laser, a semiconductor laser, a LED, a mercury lamp, an argon ion laser, etc., or various combinations thereof, may be used as the light source, depending on the selection of optical detectors, filters, monitoring, etc., (discussed in further detail herein), as generally understood by those skilled in the art.

Light from the light source reflected from the deposition surface is detected at a first optical detector 312 positioned in proximity to the reaction chamber at a predetermined angle relative to the light source (as generally recognized by those skilled in the art) so as to detect light reflected from the deposition surface and exclude incident light. The first optical detector may be configured to monitor growth rate and/or composition of film layer growth during deposition. If desired, a collection lens or other suitable device may be used to focus light reflected from the deposition surface to the first optical detector or to exclude incident light as needed. Further, narrow band filters, etc. may be used if desired.

According to the present invention, a light of an appropriate wavelength is irradiated onto the deposition surface during the process of film growth. The adsorption of a mono-atomic layer of material gas or decomposed gas onto the deposition surface is ascertained by measuring the change in intensity of the reflected light. The intensity of the reflected light is vibrated as the crystal grows molecular layer by molecular layer (atomic layer by atomic layer). Also, the amount of film growth occurring during a single cycle of gas introduction can be determined by monitoring the difference between the top and bottom of the intensity of the reflected light.

In other words, according to the present invention, the film growth per one cycle may be determined based on the intensity of a light pulse signal and the number of layers grown may be determined from the number of pulse signals. Therefore, by counting the number of the pulse signals, film growth may be monitored per unit of molecular layer (atomic layer) with the development of the growth per molecular layer (atomic layer). In this regard, methodologies for monitoring growth rate and/or compositions are generally known in the art, and any suitable methodology may be used. In certain embodiments, a filter may be arranged between the optical detector and the deposition surface to aid in excluding incidental light from the detector. In addition, the output from the optical detector may be processed by a signal amplifier and communicated to a control system or data capture system for further analysis.

In addition, light from the light source scattered by gas-phase particles formed above the deposition surface is detected at a second optical detector 314 positioned in proximity to the reaction chamber and off-axis relative to the deposition surface. The second optical detector may be positioned at any suitable angle, off-axis relative to the horizontal plane of the substrate support surface so as to be capable of detecting light scattered by gas-phase particle formation in the reaction zone above the substrate surface. By way of example, angles ranging from about 0 degrees (horizontal) to about 15 degrees above the horizontal plane (e.g., including 2, 4, 5, 6, 8, 10, 12 degrees, etc.) may be used. If desired, a collection lens or other suitable device may be used to focus light scattered by any gas-phase particle formation to the second optical detector. Further, narrow band filters, etc. may be used if desired.

As will be apparent to those skilled in the art, the processes of steps 10, 12, and 14 may be performed simultaneously with the initiation of deposition, or at any desired time after deposition begins, so as to monitor the deposition process in-situ. In certain embodiments, if desired, the step 12 and the first optical detector may be omitted, and only step 14 and the second optical detector may be used for in-situ monitoring of gas-phase particle formation without monitor growth rate and/or composition of film layer growth during deposition.

The deposition layer deposition rate and film properties may optionally be controlled (not shown), at least in part, by adjustable parameters of the reaction chamber, including the chamber temperature, pressure, and fluid flow rate, and partial pressures of the precursors, carrier gases and particle suppression compound(s). Further, in accordance with the present invention, the deposition rates may additionally be controlled based, in part, on the creation on the isothermal reaction zone above the substrate. For instance, reactant concentrations may be optimized through maintenance of a substantially isothermal reaction zone surrounding the deposition surface of the substrate, thereby aiding in control of deposition rates and efficiencies.

As described above, in accordance with certain aspects of the invention, the in-situ monitoring for the formation of parasitic gas-phase particles allows for tighter control and optimization of conditions within the reaction zone. In this way, optimized reaction conditions may be obtained in the reaction zone, while parasitic particle formation is minimized.

The processing conditions used for deposition of the deposition layer may vary depending on specific applications. The following table provides exemplary processing conditions and precursor flow rates that are generally suitable in the growth of III-V deposition layers:

| Parameter | Value |
|---|---|
| Temperature (° C.) | 500–1500 |
| Pressure (torr) | 50–1000 |
| TMG flow (sccm) | 0–50 |
| TMA flow (sccm) | 0–50 |
| TMI flow (sccm) | 0–50 |
| PH₃ flow (sccm) | 0–1000 |
| AsH₃ flow (sccm) | 0–1000 |
| NH₃ flow (sccm) | 10–100,000 |
| HCl flow (sccm) | 0–500 |
| N₂ flow (sccm) | 0–100,000 |
| Ar flow (sccm) | 0–10000 |
| H₂ flow (sccm) | 0–100,000 |

As will be evident from the preceding description, a process might not use flows of all the precursors in any given process. For example, growth of GaN might use flows of TMG, NH₃, and N₂ in one embodiment; growth of AlGaN might use flows of TMG, TMA, NH₃, and H₂ in another embodiment, with the relative flow rates of TMA and TMG selected to provide a desired relative Al:Ga stoichiometry of the deposited layer; and growth of InGaN might use flows of TMG, TMI, NH₃, N₂, and H₂ in still another embodiment, with relative flow rates of TMI and TMG selected to provide a desired relative In:Ga stoichiometry of the deposited layer.

The reaction zone conditions may be set to form the deposition layer with a deposition rate of, for example, about 4 μm/hr or more, about 5 μm/hr or more, about 10 μm/hr or more, about 25 μm/hr or more, or about 50 μm/hr or more. Such deposition rates are improved, as compared to those deposition rates from models wherein in-situ monitoring methodologies are not used to minimize particle formation. The deposition time may be, for example, about 1, 5, 10, 15, 20, 30, 45, or 60 minutes or more. Deposition layer thicknesses may vary, depending on the type of layer, as recognized by those skilled in the art, e.g., a nucleation layer having a thickness of about 100 Å to about 1000 Å while epitaxial layers may be, e.g., 5 μm or more.

In other embodiments, at least the second optical detector may be used to monitor for gas-phase particles during chamber cleaning processes. By way of example, chamber clean end-points may be determined based on desired scattered light readings at the second optical detector. Optionally, if desired, substrate support surface clean end-points may separately be monitored based on desired reflected light readings at the first optical detector.

### Exemplary In-Situ Processing System

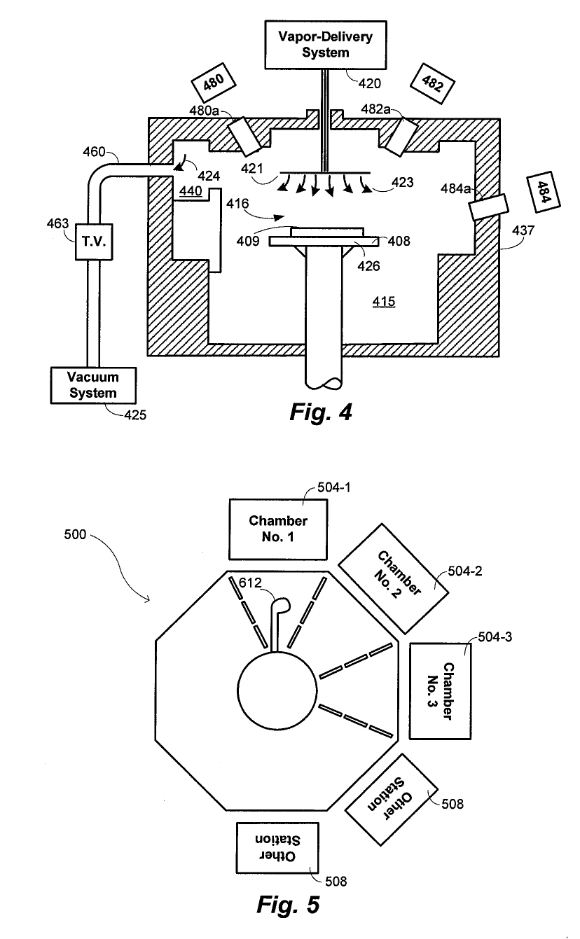

FIG. 4 is a simplified diagram of an exemplary chemical vapor deposition (“CVD”) system, illustrating the basic structure of a chamber in which individual deposition steps can be performed. This system is suitable for performing thermal, sub-atmospheric CVD (“SACVD”) processes, as well as other processes, such as reflow, drive-in, cleaning, etching, deposition, and gettering processes. In some instances multiple-step processes can still be performed within an individual chamber before removal for transfer to another chamber. The major components of the system include, among others, a reaction chamber 415 that receives process and other gases from a gas or vapor delivery system 420, a vacuum system 425, and a control system (not shown). In addition, the systems also include a light source 480, first optical detector 482, and second optical detector 484. Additional light sources (not shown) and/or optical detectors (not shown) at predetermined angles relative to the light source and/or substrate may optionally be included if additional monitoring points, wavelengths, etc. are desired. These and other components are described in more detail below. While the drawing shows the structure of only a single chamber for purposes of illustration, it will be appreciated that multiple chambers with similar structures may be provided as part of a cluster tool, each tailored to perform different aspects of certain overall fabrication processes.

The CVD apparatus includes an enclosure assembly 437 that forms reaction chamber 415 with a reaction zone 416. A gas distribution structure 421 disperses reactive gases and other gases, such as purge gases, toward one or more substrates 409 held in position on a substrate support structure 408, generally configured as a susceptor. Heaters 426 can be controllably moved between different positions to accommodate different deposition processes as well as for an etch or cleaning process. A center board (not shown) includes sensors for providing information on the position of the substrate.

Light source 480 is positioned in proximity to enclosure assembly 437 of reaction chamber 415, and optical access port 480a is aligned with the light source so as to allow the light beam generated by the light source 480 to enter reaction chamber 415 and pass to the surface of the one or more substrate 409 held in position on the substrate support structure 408. Again, a light beam is generated by light source 480 at a desired wavelength, and passed into reaction chamber 415 through visual access port 480a to the surface of substrate 409. If desired, various narrow band filters, choppers, etc. may be used (not shown). In certain embodiments, a red or green laser, a He—Ne laser, a semiconductor laser, a LED, a mercury lamp, an argon ion laser, etc., or various combinations thereof, may be used as the light source, depending on the selection of optical detectors, filters, monitoring, etc., as generally understood by those skilled in the art.

First optical detector 482 may be positioned in proximity to enclosure assembly 437 of reaction chamber 415 at a predetermined angle relative to light source 480 so as to be capable of detecting light reflected from the surface of substrate 409 while excluding incident light. (through optical access port 482a). Any suitable optical detector known in the art for such purposes may be used, such as but not limited photodetectors including Si photodiodes, as generally understood by those skill in the art. The first optical detector may be configured to monitor growth rate and/or composition of film layer growth during deposition. If desired, a collection lens or other suitable device (not shown) may be used to focus light reflected from the deposition surface to the first optical detector or to exclude incident light as needed. Further, narrow band filters, etc. may be used if desired (not shown). See, e.g., U.S. Pat. No. 5,525,156, which is herein incorporated by reference.

Second optical detector 484 may be position in proximity to enclosure assembly 437 of reaction chamber 415 off-axis relative to substrate 409 so as to be capable of detecting light scattered by gas-phase particle formation in reaction zone 416 (through optical access port 484a). Any suitable optical detector known in the art for such purposes may be used, such as but not limited photodetectors including Si photodiodes, as generally understood by those skill in the art. Again, the second optical detector may be positioned at any suitable angle, off-axis relative to the horizontal plane of the substrate support surface so as to be capable of detecting light scattered by gas-phase particle formation in the reaction zone above the substrate surface. By way of example, angles ranging from about 0 degrees (horizontal) to about 15 degrees above the horizontal plane (e.g., including 2, 4, 5, 6, 8, 10, 12 degrees, etc.) may be used. If desired, a collection lens or other suitable device (not shown) may be used to focus light scattered by any gas-phase particle formation to the second optical detector. Further, narrow band filters, etc. may be used if desired (not shown).

Different structures may be used for heaters 426. For instance, some embodiments of the invention advantageously use a pair of plates in close proximity and disposed on opposite sides of the substrate support structure 408 to provide separate heating sources for the opposite sides of one or more substrates 409. Merely by way of example, the plates may comprise graphite or SiC in certain specific embodiments. In another instance, the heaters 426 include an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heaters 426 exposed to vacuum chamber 415 are made of a ceramic material, such as aluminum oxide (Al₂O₃ or alumina) or aluminum nitride. In another embodiment, the heaters 426 comprises lamp heaters. Alternatively, a bare metal filament heating element, constructed of a refractory metal such as tungsten, rhenium, iridium, thorium, or their alloys, may be used to heat the substrate. Such lamp heater arrangements are able to achieve temperatures greater than 1200° C., which may be useful for certain specific applications.

In certain aspects of the invention, one or more heaters 426 may optionally be incorporated into substrate support structure 408 and/or top-plate 410, so as to partially aid in controlling the temperature gradient in the reaction zone 416. Alternatively, the configuration and/or placement of the one or more heaters 426 in the enclosure assembly 437 may partially aid in control of temperature gradients.

Reactive and carrier gases are supplied from the gas or vapor delivery system 420 through supply lines to the gas distribution structure 421. In some instances, the supply lines may deliver gases into a gas mixing box to mix the gases before delivery to the gas distribution structure. In other instances, the supply lines may deliver gases to the gas distribution structure separately, such as in certain showerhead configurations described below. As shown, the gas or vapor delivery system 420 directly enters the substantially isothermal reaction zone 416 through the top. Alternatively, the delivery system may distribute gases into the reaction zone through the side (not shown), so that the reaction gases flow from the side over the surface of the substrate wafer 409.

The gas or vapor delivery system 420 includes a variety of sources and appropriate supply lines to deliver a selected amount of each source to chamber 415 as would be understood by a person of skill in the art. Generally, supply lines for each of the sources include shut-off valves that can be used to automatically or manually shut-off the flow of the gas into its associated line, and mass flow controllers or other types of controllers that measure the flow of gas or liquid through the supply lines. Depending on the process run by the system, some of the sources may actually be liquid or solid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. Alternatively, liquid precursor may be introduced into the gas phase by flowing gases over a liquid source that will react at the liquid-gas interface, for instance, HCl (g)+Ga (1)→GaCl (g)+0.5H₂ (g). During deposition processing, gas supplied to the gas distribution structure 521 is vented toward the substrate surface (as indicated by arrows 423), where it may be uniformly distributed radially across the substrate surface in a laminar flow.

Purging gas may be delivered into the vacuum chamber 415 from gas distribution structure 421 and/or from inlet ports or tubes (not shown) through the bottom wall of enclosure assembly 437. Purge gas introduced from the bottom of chamber 415 flows upward from the inlet port past the heater 426 and to an annular pumping channel 440. Vacuum system 425 which includes a vacuum pump (not shown), exhausts the gas (as indicated by arrows 424) through an exhaust line 460. The rate at which exhaust gases and entrained particles are drawn from the annular pumping channel 440 through the exhaust line 560 is controlled by a throttle valve system 463.

The temperature of the walls of reaction chamber 415 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during other processes, or to limit formation of deposition products on the walls of the chamber. Gas distribution manifold 421 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The system controller controls activities and operating parameters of the deposition system. The system controller may include a computer processor and a computer-readable memory coupled to the processor. The processor executes system control software, such as a computer program stored in memory. The processor operates according to system control software (program), which includes computer instructions that dictate the timing, mixture of gases, chamber pressure, chamber temperature, microwave power levels, pedestal position, and other parameters of a particular process. Control of these and other parameters is effected over control lines that communicatively couple the system controller to the heater, throttle valve, and the various valves and mass flow controllers associated with gas delivery system 520.

In certain embodiments, the system controller may be interfaced with the first and/or second detector so as to control system parameters based, at least in part, on reaction conditions monitored via the detectors. For instance, partial pressures of reactant gases delivered through gas delivery system 520 may be optimized and controlled based, at least in part, on readings from at least the second optical detector regarding the formation of gas-phase particles in reaction zone 416. By way of example, the system controller may maximize reactant partial pressures within reaction zone 416 to a level just above, at or just below the point where gas-phase particles are detected by the second optical detector. Film composition, growth rate, quality, etc. may also be monitored by at least the first detector, and information from the first detector may be used in optimization of system controller parameters.

The physical structure of the cluster tool is illustrated schematically in FIG. 5. In this illustration, the cluster tool 500 includes three processing chambers 604 and two additional stations 508, with robotics 512 adapted to effect transfers of substrates between the chambers 504 and stations 508. The structure permits the transfers to be effected in a defined ambient environment, including under vacuum, in the presence of a selected gas, under defined temperature conditions, and the like. Optical access is provided to a transfer chamber in which the transfers are affected through a window 510. A particular advantage of having optical access provided through the transfer chamber, as opposed to through one of the processing chambers 504, is that the window 510 may be made relatively large. A concern with providing optical access to processing chambers is the disturbance that a window or similar structure will have on processing characteristics taking place within the chamber. Since no processing takes place directly on the substrate in the transfer chamber, such concerns are avoided. A variety of optical elements may be included within or outside the transfer chamber to direct the light as desired.

Although the invention is described herein as being implemented in software and executed upon a general purpose computer, those of skill in the art will realize that the invention could be implemented using hardware such as an application specific integrated circuit (ASIC) or other hardware circuitry. As such, it should be understood that the invention can be implemented, in whole or in part, is software, hardware or both. Those skilled in the art will also realize that it would be a matter of routine skill to select an appropriate computer system to controls the systems described herein.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. An apparatus for in-situ monitoring of gas-phase particle formation during metal organic chemical vapor deposition (MOCVD) of Group III-V nitride films; the apparatus comprising:
an MOCVD reaction chamber configured for deposition of a Group III-V nitride film;
at least one light source capable of generating a light beam at a desired wavelength and positioned relative to the MOCVD reaction chamber so as to pass the light beam into the MOCVD reaction chamber to the surface of a sample disposed within the MOCVD reaction chamber during deposition of a Group III-V nitride film;
a first optical detector capable of detecting light reflected from the surface of the sample disposed within the MOCVD reaction chamber and positioned at a predetermined angle relative to at least one light source so as to receive reflected light from the sample and exclude incident light, wherein the first optical detector is configured to monitor growth rate and/or composition of the Group III-V nitride film during deposition; and
a second optical detector capable of detecting light scattered by gas-phase particles formed above the surface of the sample disposed within the MOCVD reaction chamber, and positioned off-axis relative to the sample so as to receive scattered light from gas-phase particles, wherein the second optical detector is configured to monitor gas-phase particle formation during deposition of the Group III-V nitride film.

2. The apparatus of claim 1, further comprising a control module interfaced with the MOCVD reaction chamber, the first optical detector, and the second optical detector, wherein the control module is configured to control operating parameters of the MOCVD reaction chamber to minimize gas-phase particle formation based, in part, on readings from the second optical detector.

3. The apparatus of claim 2, wherein the control module is at least in part configured to modify partial pressures of reactant gases if gas-phase particle formation is detected at the second optical detector.

4. The apparatus of claim 1, further comprising a collection lens positioned off-axis relative to the at least one light source so as to focus light scattered by gas-phase particle formation to the second optical detector.

5. The apparatus of claim 1, wherein the at least one light source is a red or white laser source.

6. A method for in-situ monitoring of gas-phase particle formation during metal organic chemical vapor deposition (MOCVD) of Group III-V nitride films; the method comprising:
initiating deposition of a Group III-V nitride film on a substrate in a MOCVD reaction chamber;
generating a light beam at a desired wavelength and directing the light beam within the MOCVD reaction chamber so as to pass the light beam through the MOCVD reaction chamber to the surface of the substrate disposed within the MOCVD reaction chamber during deposition of the Group III-V nitride film;
detecting light reflected from the surface of the substrate disposed within the MOCVD reaction chamber during deposition of the Group III-V nitride film at a first optical detector and positioned at a predetermined angle relative to at least one light source so as to receive reflected light from the substrate and exclude incident light, wherein the first optical detector is configured to monitor growth rate and/or composition of the Group III-V nitride film during deposition; and
detecting light scattered by gas-phase particles formed above the surface of the substrate disposed within the MOCVD reaction chamber at a second optical detector positioned off-axis relative to the sample so as to receive scattered light from gas-phase particles, wherein the second optical detector is configured to monitor gas-phase particle formation during deposition of the Group III-V nitride film.

7. The method of claim 6, further comprising controlling operating parameters of the MOCVD reaction chamber to minimize gas-phase particle formation based, in part, on readings from the second optical detector.

8. The method of claim 7, wherein the operating parameter that is controlled is a partial pressure of one or more reactant gas flows.

9. The method of claim 6, further comprising focusing light scattered by any gas-phase particle formation to the second optical detector via a collection lens positioned off-axis relative to the at least one light source.
